(19) United States
(12) Patent Application Publication
(10) Pub. No.: US 2023/0209763 A1
(43) Pub. Date: Jun. 29, 2023

(54) MODULAR AND SCALABLE POWER DISTRIBUTION

(71) Applicant: Panduit Corp., Tinley Park, IL (US)

(72) Inventors: Ronald A. Nordin, Naperville, IL (US); Masud Bolouri-Saransar, Orland Park, IL (US); Surendra Chitti Babu, Naperville, IL (US); Francis C. Cheo, Arlington Heights, IL (US); Daniel E. Host, Orland Park, IL (US); Michael D. Asztalos, Orland Park, IL (US); Eric Beaupre, Palos Park, IL (US)

(73) Assignee: Panduit Corp., Tinley Park, IL (US)

(21) Appl. No.: 17/898,976

(22) Filed: Aug. 30, 2022

Related U.S. Application Data
(63) Continuation-in-part of application No. 17/465,097, filed on Sep. 2, 2021.
(60) Provisional application No. 63/076,430, filed on Sep. 10, 2020.
(60) Provisional application No. 63/301,521, filed on Jan. 21, 2022.
(60) Provisional application No. 63/315,184, filed on Mar. 1, 2022.
(60) Provisional application No. 63/345,138, filed on May 24, 2022.

(51) Int. Cl. H05K 7/14; H02B 1/20

(52) U.S. Cl. CPC H05K 7/1492; H02B 1/20

(57) ABSTRACT

A modular power distribution system includes using power extension modules and power distribution modules. The power extension modules are configured to route inputted power to another power extension module or a power distribution module. The power distribution modules are configured to route power from a power extension module to one or more racks or cabinets in a data center.

### CROSS REFERENCE TO RELATED APPLICATION(S)

This application is a continuation-in-part of U.S. patent application Ser. No. 17/465,097, filed Sep. 2, 2021 and also claims the benefit of U.S. Provisional Patent Application Ser. No. 63/076,430, filed Sep. 10, 2020; U.S. Provisional Patent Application Ser. No. 63/301,521, filed Jan. 21, 2022; U.S. Provisional Patent Application Ser. No. 63/315,184, filed Mar. 1, 2022; and U.S. Provisional Patent Application Ser. No. 63/345,138, filed May 24, 2022, the entirety of which is hereby incorporated by reference herein.

### FIELD OF THE INVENTION

The present invention relates generally to power distribution systems and more specifically a modular power distribution system that combines the best features of a Power Bus system and a point-to-point wiring system.

### BACKGROUND

The power from the electric utility must be distributed efficiently to IT Equipment contained within Cabinets in Data Centers (or in Enterprise or Industrial settings). This power is typically distributed in 3-phase Delta or Wye configurations to each of the cabinets. The power is then connected to the Cabinet's Rack-PDU (Power Distribution Unit) where the power is distributed to each of the IT-Equipment. Today's methods of distributing this power are designed specifically for the particular application.

As shown in FIG. 1, power first enters a facility from the electric utility at a high voltage level (typically 35 kV), where it is first stepped down to a low voltage (e.g., 480 VAC) and routed to a Mains Switch Gear. Here a selection between the Utility power or a backup generator is selected. After the switch gear, the power is typically stepped down again to either 415 or 208 prior to or within the distribution cabinets. The distribution cabinets than route power to each of the PDU's where it is further distributed to the cabinets containing IT-Equipment.

Once the power is routed to the Data Hall's PDU, traditionally it has been distributed to the cabinets containing IT-Equipment by either point to point wiring or through a power bus method (see FIGS. 2A and 2B below). FIG. 2A shows a block diagram of a power bus method of distributing power to each cabinet's rack-based PDU. Power Bus systems are typically routed above the cabinets only. The rack-based PDU(s) connects to a “Tap-Off-Point” box that is connected to the power bus. These Tap-off-points are required to contain a breaker and optionally can have a power measurement capability. Some of the drawbacks of a power bus system is the material cost of the equipment, the installation cost, and the consultative services required to design the power distribution system.

FIG. 2B shows a block diagram of a point-to-point wiring power distribution system. Power cables run from each of the rack-based PDUs to either a power distribution cabinet or a remote power panel. The point-to-point wiring can be either overhead or under floor (as shown). Some of the drawbacks of a point-to-point wiring method of power distribution include initial installation cost and the cost of making changes to the system.

### SUMMARY

A modular power distribution system includes using power extension modules and power distribution modules. The power extension modules are configured to route inputted power to another power extension module or a power distribution module. The power distribution modules are configured to route power from a power extension module to one or more racks or cabinets in a data center. In one embodiment, the modular power distribution system can also include power feed modules and/or breaker modules.

### BRIEF DESCRIPTION OF THE FIGURES

FIG. 1 shows a block diagram on how power is distributed in a data center.

FIG. 2A shows how power is distributed to cabinets using a Power Bus system.

FIG. 2B shows how power is distributed to cabinets using point-to-point wiring.

FIG. 3A shows a modular power distribution system according to the present invention.

FIG. 3B shows the power distribution panel for the system of FIG. 3A.

FIG. 3C shows the power distribution and power extension modules for the system of FIG. 3A.

FIG. 4A shows the power distribution module wiring.

FIG. 4B shows the power extension module wiring.

FIG. 5A shows the breaker module.

FIG. 5B shows the power feed module.

FIG. 6A shows the overall system of a second embodiment of a modular power distribution system.

FIG. 6B shows the power feed panel of the embodiment of FIG. 6A.

FIG. 7 is a chart showing the contact arrangement for the various modules.

FIG. 8 shows isometric views of the male and female contact housings.

FIG. 9 shows the UL 857 Finger Probe.

FIG. 10 is a cross-sectional view showing staggered contacts in the female housing.

FIG. 11 is a cross sectional view showing the engagement of the contacts between the male and female housings.

FIG. 12 is another cross sectional view with a chart showing the creepage and clearance distances from UL 587.

FIG. 13A shows the power connectors being used to electrically connect two modules.

FIG. 13B is a closer view of the power connectors of FIG. 13A.

FIG. 13C is also a closer view of the power connectors of FIG. 13A.

FIG. 14 shows the components in a mechanical coupling mechanism to connect two modules.

FIG. 15 is an exploded view of the coupling mechanism of FIG. 14.

FIG. 16 shows an embodiment of a coupling mechanism similar to the one of FIG. 14 but with alignment/support bars.

FIG. 17A shows the first step in the sequence of steps in securing the coupling mechanism of FIG. 14.

FIG. 17B shows the second step in the sequence of steps in securing the coupling mechanism of FIG. 14.

FIG. 17C shows the third step in the sequence of steps in securing the coupling mechanism of FIG. 14.

FIG. 18 shows two modules coupled together through the coupling mechanism of FIG. 14.

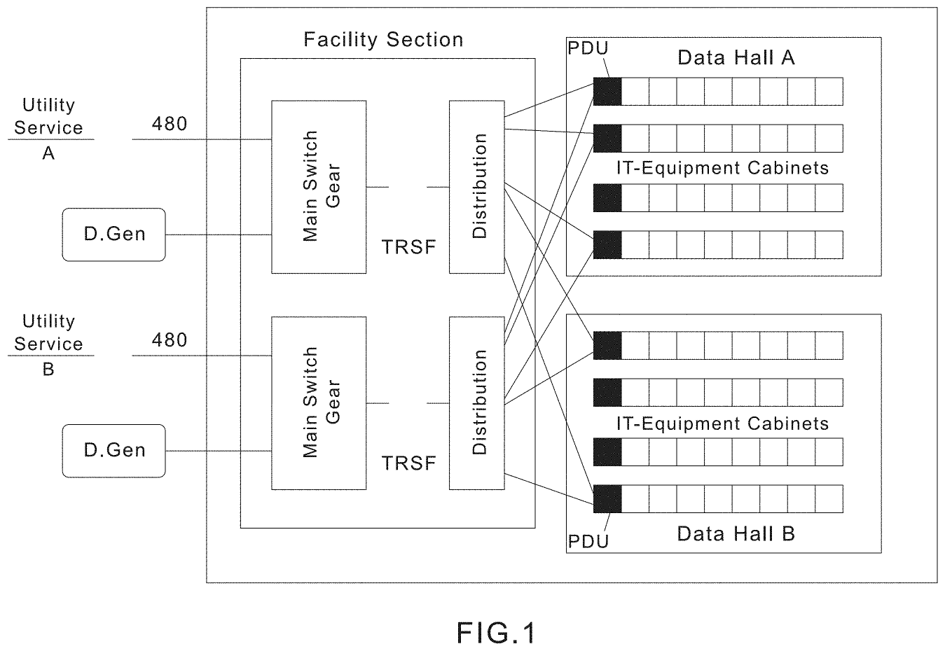

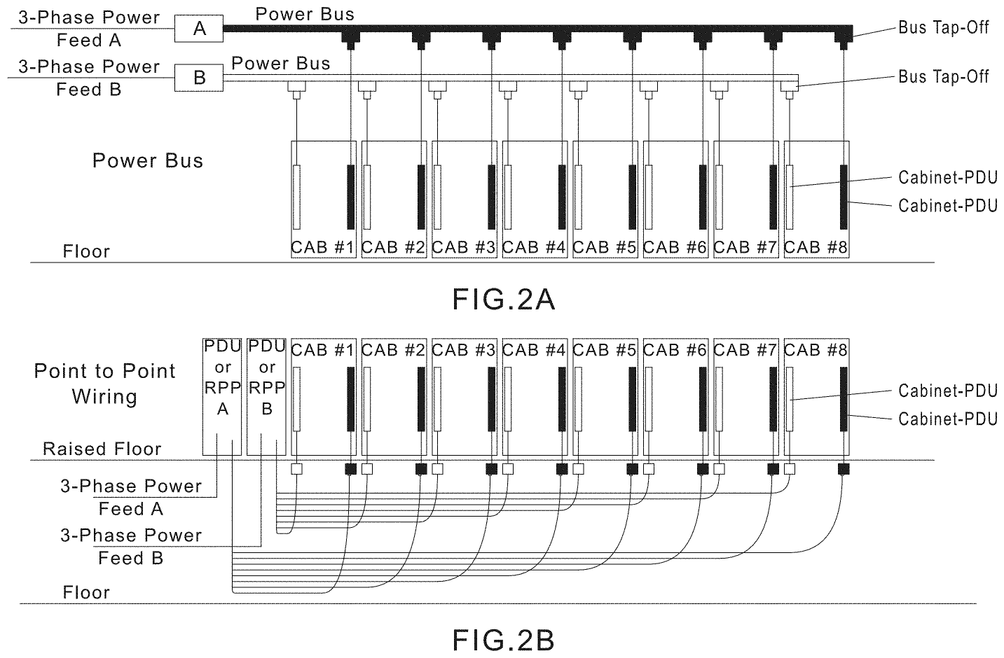

### DETAILED DESCRIPTION OF THE INVENTION

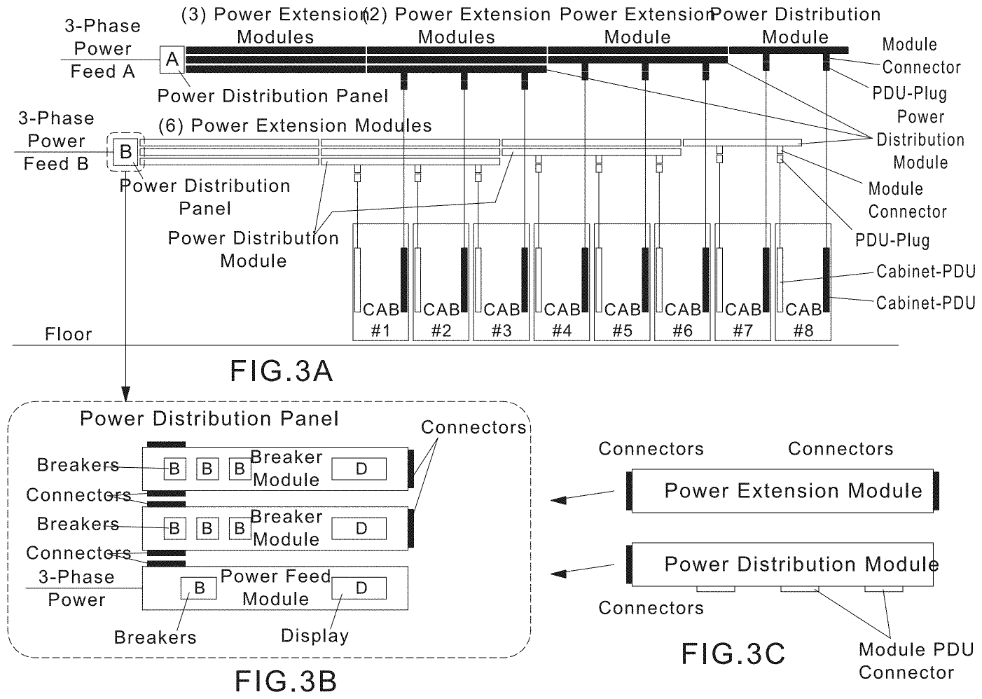

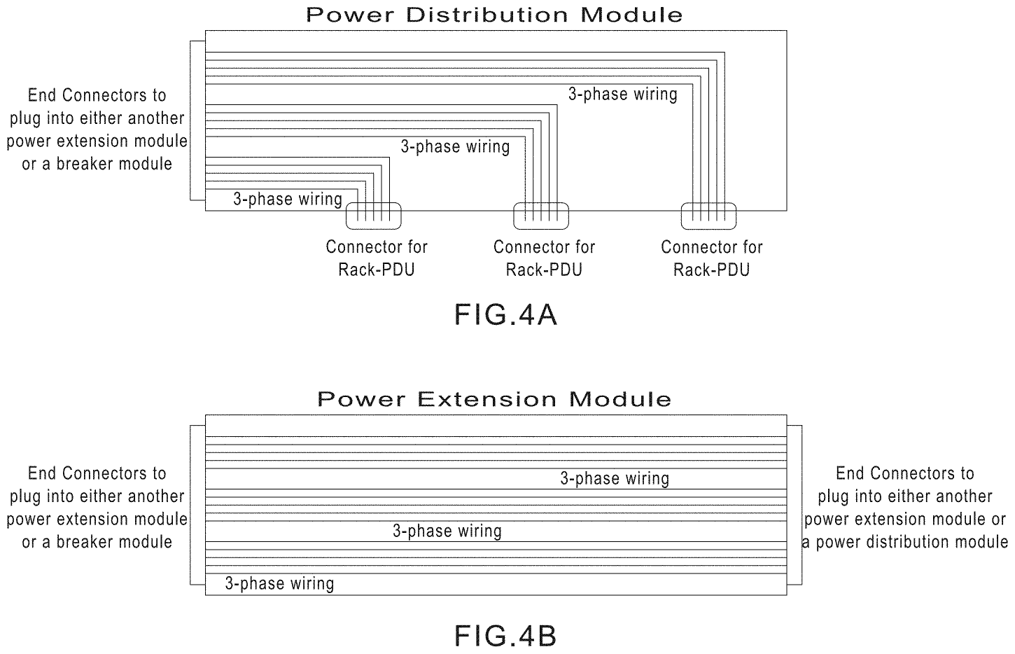

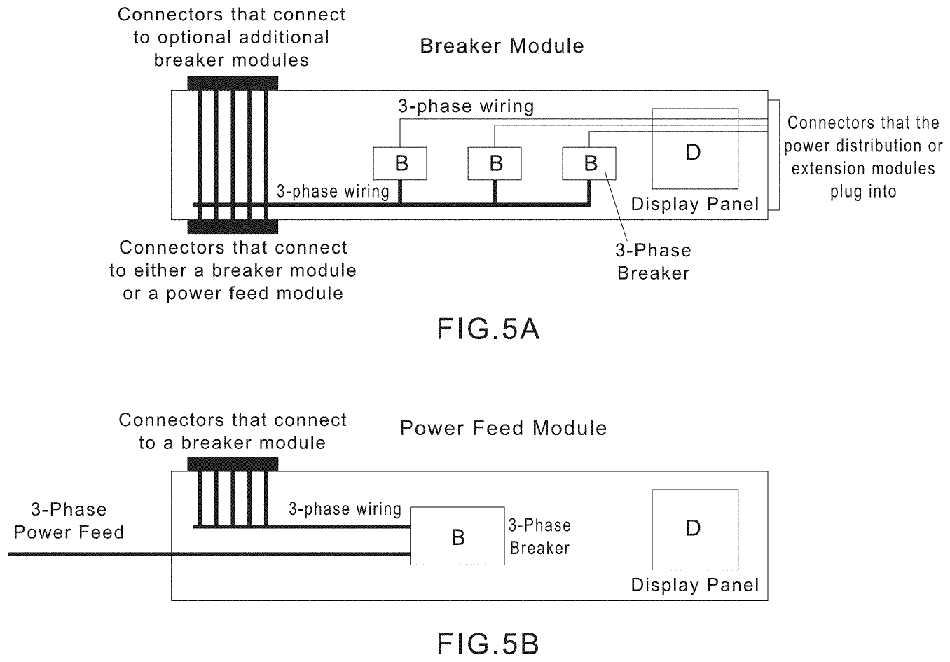

A novel technique of distributing power is shown in FIG. 3A. This technique combines the best features of the Power Bus method and the best features of point-to-point wiring method. This technique offers a modular and scalable solution for the distribution of power. Each of the rack-based PDUs plug into a Power Distribution module. The Power Distribution module is equipped with outlets where a multiple of Rack-PDUs can plug into (a preferred number is three or four). (Additionally, the Power Distribution Module can contain branch circuit power monitoring circuitry). The Power Extension Modules do not have any outlets and its primary purpose is serve as interface between the Breaker Module and Power Distribution Module. (Additionally, the Power Extension Modules can transport the branch circuit monitoring information form the Power Distribution Modules back to the Power Feed panel). The Power Distribution module connects to as many of the Power Extension modules as necessary to transfer power from the power distribution panel back to the Power Feed Panel(see FIG. 3A). These Power Distribution and Extension modules are connectorized at the ends to plug into one another as well as plugging into the breaker module within the power distribution panel (see FIG. 3C and further shown in FIGS. 4A and 4B). The Power Distribution panel is shown in FIG. 3B and further shown in FIGS. 5A and 5B. It is a modular and scalable system composing of two modules: the power feed module and the breaker module. The power feed module connects to the main power feed cable (typically a 3-phase delta or wye configuration) and to the breaker modules. The power feed module can contain a high-power breaker for the main power feed (and optionally a display panel to indicate the power levels being drawn from the main power feed). The breaker modules can tap into the power from the power feed module and connect to other breaker modules and either the power distribution or extension modules. The breaker module contains a current breaker for each of the power lines connecting to the rack-based PDUs (three 3-phase breakers are shown in FIG. 3C) and an optional display panel to indicate the power levels in each rack-PDU that it is connected to. Note the function of the Breaker module can be integrated into the power Distribution modules and the Extension modules.

The advantages of this power distribution method are:
Lower part cost and simpler design;
A lower cost of installation;
Ease of installation and ease of scalability to larger systems; and
No consultative services required for the system design.

The technique provides the flexibility, scalability, and modularity of a Power Bus system at the cost of a point-to-point system.

FIGS. 4A and 4B describes the wiring for both the power distribution and extension modules. FIG. 4A shows the wiring diagram for the power distribution module which connects the end connector to each of the PDU connectors. FIG. 4B shows the wiring diagram for the power extension module which connects the two end connectors together.

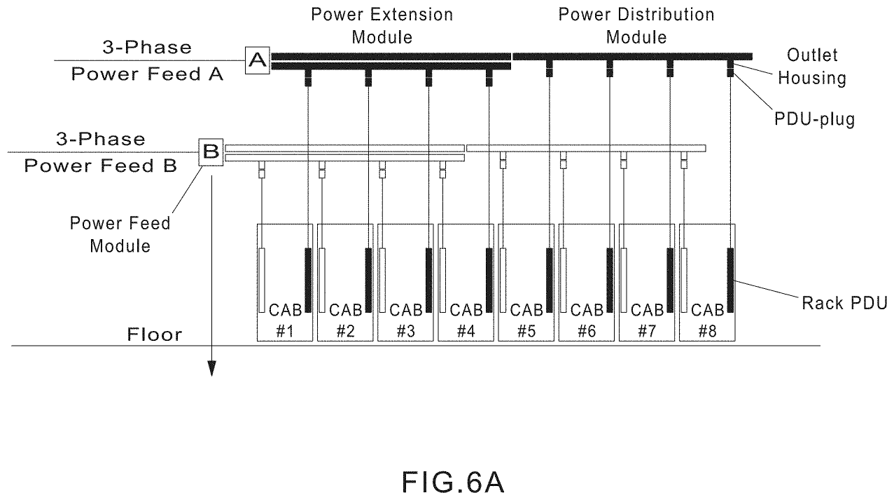

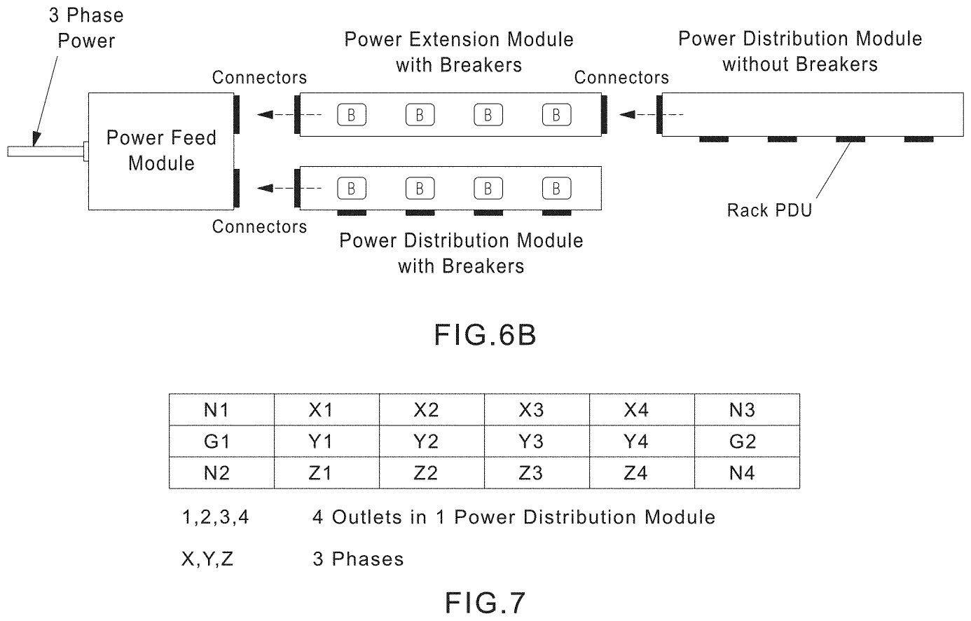

A second embodiment which uses modular outlets in the power distribution module is shown in FIGS. 6A and 6B and described.
1. Power Feed Module (PFM): PFM is designed to work with various 3-phase power configurations from building such as 208V Delta, 208V Wye or 415V Wye. The main power feed cable is fed into the PFM and power is distributed within to the end connectors and eventually to the connected Power Extension Module (PEM) and Power Distribution Module (PDM). Depending on the number of cabinets that need power, the PFM can be scaled. In this example, 8 cabinets are powered by the system; hence two rows of PEM/PDM combination is shown.
2. Power Extension Module (PEM) and Power Distribution Module (PDM): In this embodiment shown with 8 cabinets (FIGS. 6A and 6B), Power Distribution Module is equipped with 4 circuit breakers and 4 outlet housings where Rack-PDUs can plug into (# of outlet housings/circuit breakers can be increased or decreased in other embodiments according to the number cabinets being powered by one PDM). Since the Outlet Housings are modular, different Outlet Housings can be used depending on the equipment that is being powered. Power Extension Module is equipped with 4 circuit breakers in this embodiment and could have more or fewer depending on the cabinets being powered by PDM. Subsequent PDM connected to PEM will not have circuit breakers.

As mentioned for PFM, for a layout with number of cabinets higher than 8, PFM can be scaled up along with increasing the # of PEMs and PDMs. For a 4-cabinet layout, PEM will not be used.

PEMs and PDMs are not restricted to any particular cabinet widths. Different length of PEMs and PDMs can be made to match the cabinet widths as well as “spacer” PEMs to accommodate in-row deployments such as vertical managers, in-row coolers, etc. that do not require an electrical outlet.

In different embodiments, this design can be adapted to provide power to non-IT equipment that are outside cabinets as well; for example, by using a different Outlet Housings.

Connectorizing these different modules such as Power Feed Module, Power Extension Module and Power Distribution Module is one of the key aspects of this design. In order to achieve this, power connector with multiple contact terminals will be used to make the necessary electrical connections between different modules.

In one implementation of such a design, each power distribution module provides power to 4 cabinets thereby requiring 18 contact terminals as shown in FIG. 7 (4 contacts each for Phase X, Y, Z, Neutral and 2 shared grounds). As a result, the connector housing was developed to house all 18 contacts. In this embodiment, a commonly available type of contact terminals are used. Plastic housings could be designed appropriately for different type of terminal contacts. Within the power connector, multitude of contact terminals and thereby their corresponding phases, neutral and ground are laid in a specific manner such that symmetry is accomplished. As a result, the power connector does not require a certain orientation and greatly aids during the assembly process and minimize error.

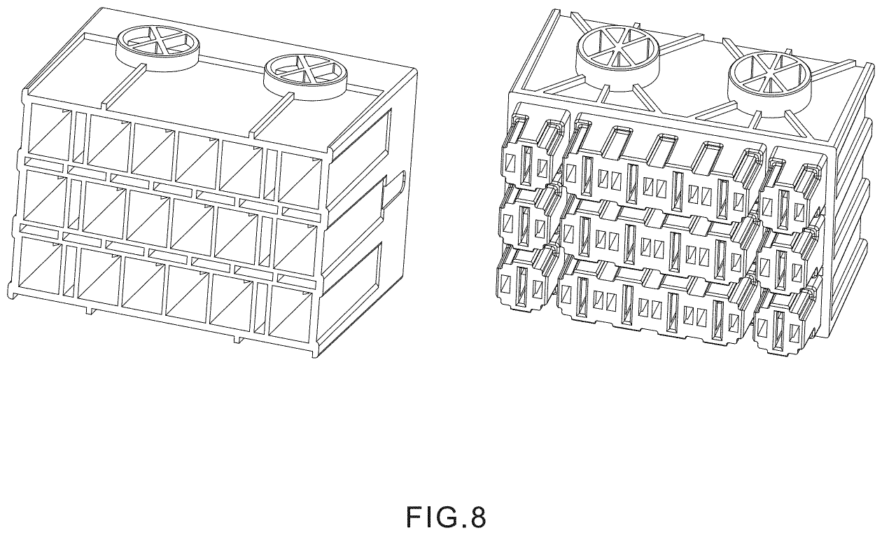

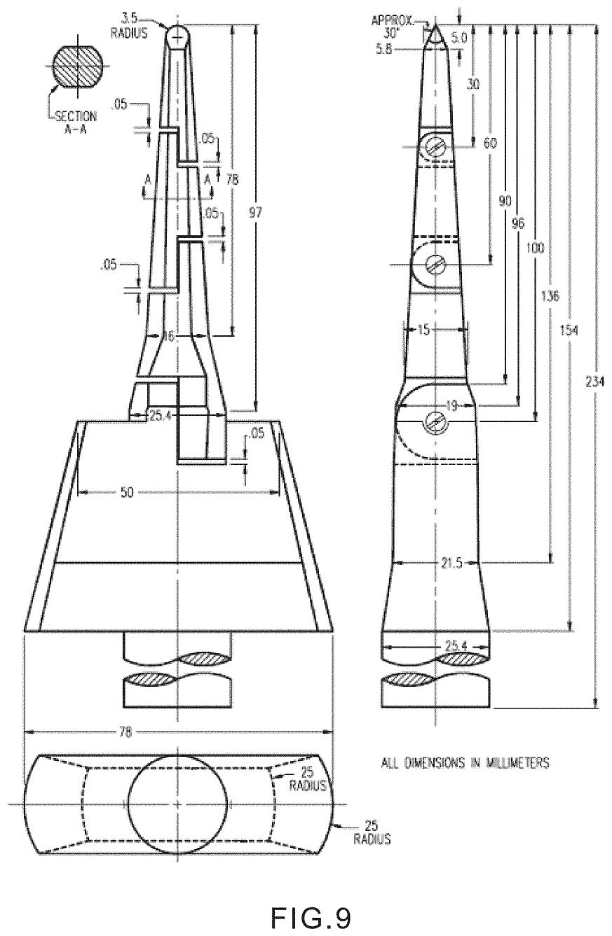

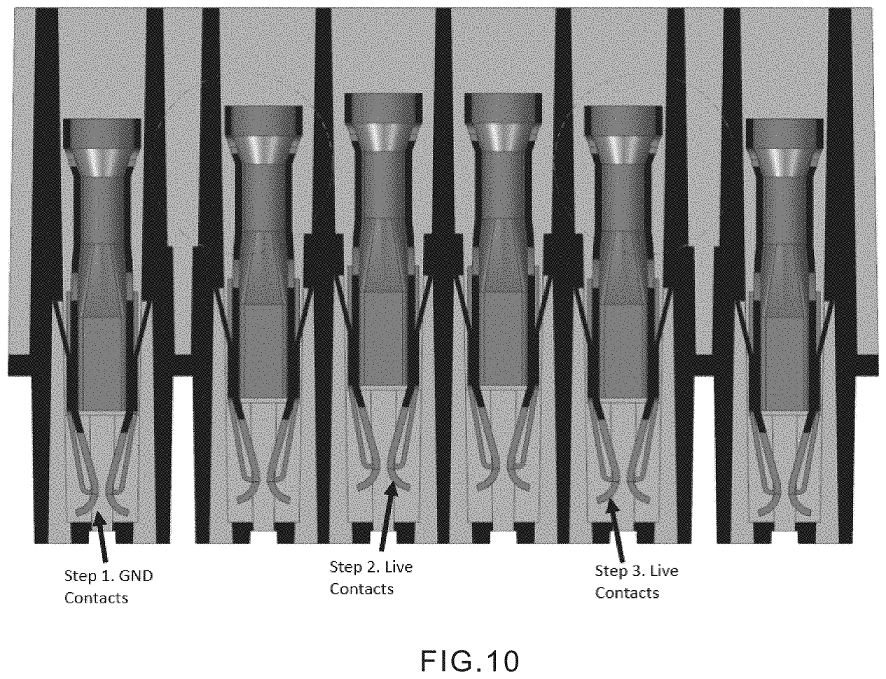

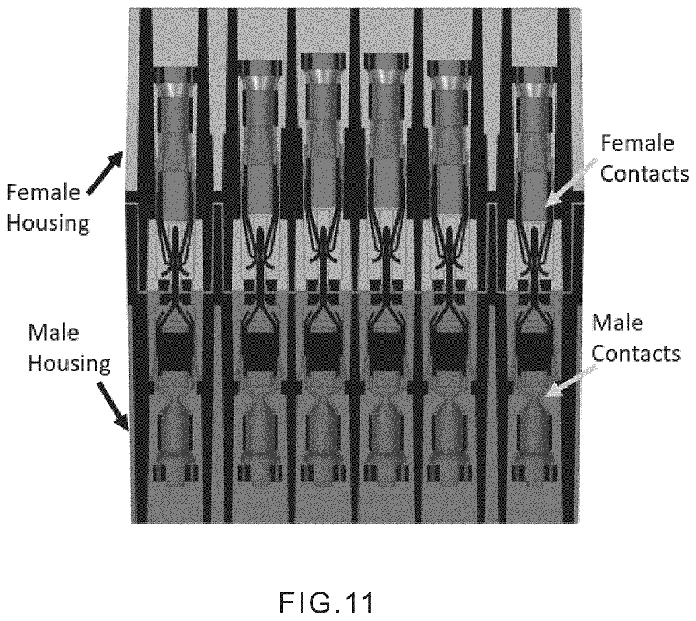

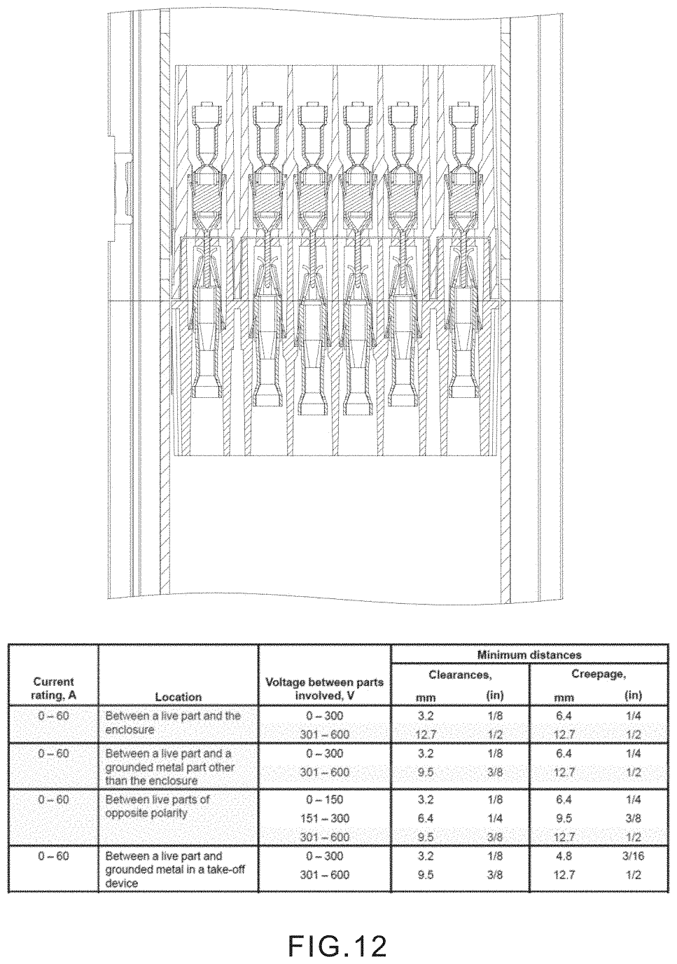

The connector housing is designed to ensure the following:
1. Finger-safety: The opening in the female housing (as shown in FIG. 8) and placement of the receptable contacts within the housing is designed such that it is compliant to Section 7.4.6 in UL 857 (FIG. 9). The male contacts are not energized until they have engaged with the female power connector.
2. Ground contact safety: Ground receptacle contacts in the female housings (FIG. 10) are positioned ahead of live contacts such that ground contacts are the first to engage and last to disconnect.
3. Reduction in the connector insertion force: Individual contacts have considerable insertion force (˜10 lbs) thereby reducing the contact resistance. In order to reduce the amount of insertion force during installation, contacts are staggered (FIG. 11) in three stages such that only few contacts are inserted at a time rather than all contacts in one stage. This arrangement creates different timing in response to the peak force of each stage. In this current embodiment, total of 18 contacts would have required approximately 180 lbs. and by designing three stages of insertion, required insertion force is reduced at each stage.
4. Creepage and clearance distances are maintained: Connector housing is designed to meet the required creepage and clearance as required by UL857 as shown in FIG. 12.

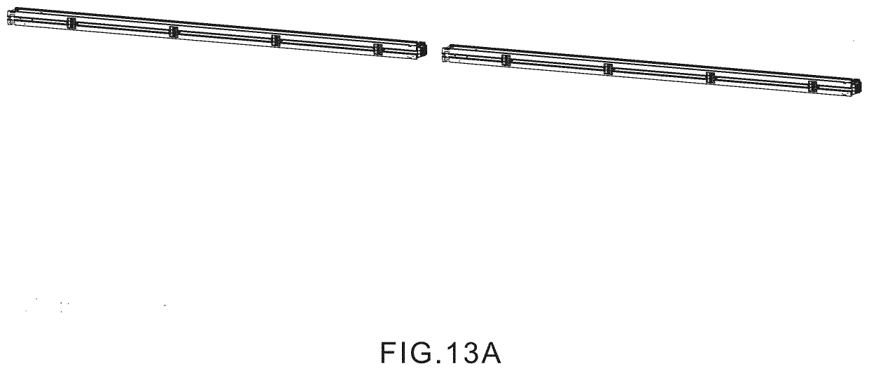

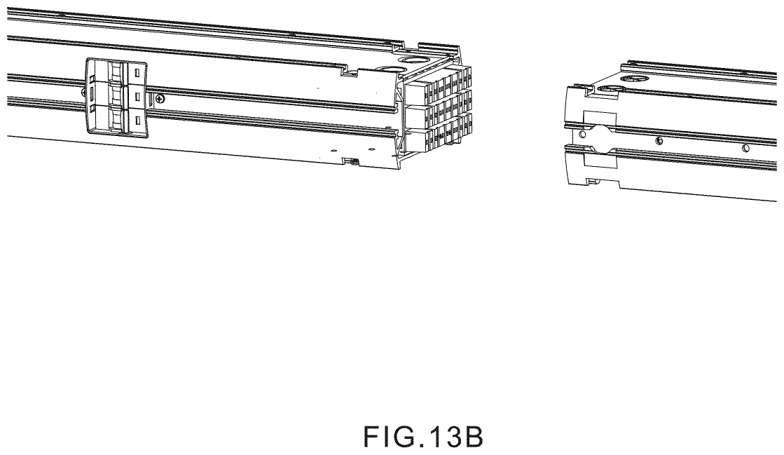

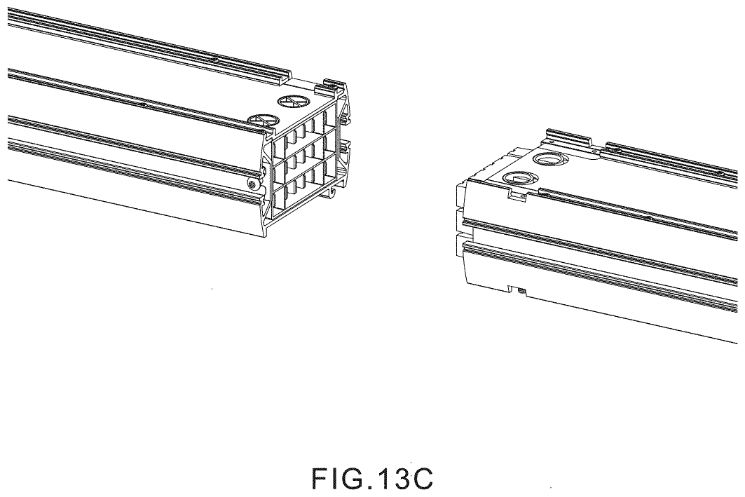

A new mechanism is developed as detailed in this document that enables insertion and removal of one module into another easier. This mechanism can be used with any regular tool such as nut driver, ratchet or it could be also used with aid of a power tool. The end of Power Distribution Modules, Power Extension Modules and Power Feed Modules are connectorized using the power connectors. An example of the power modules with power connectors which would be engaged is shown in FIGS. 13A-C.

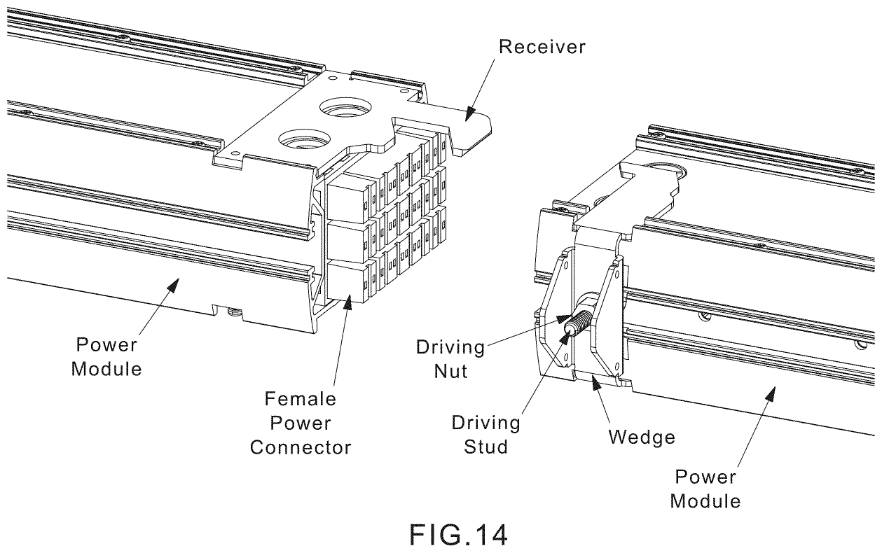

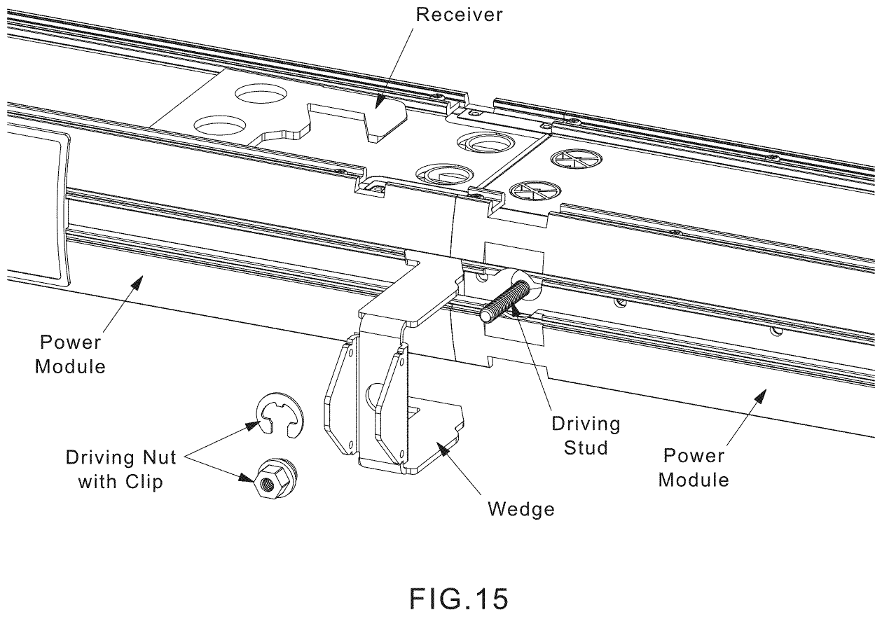

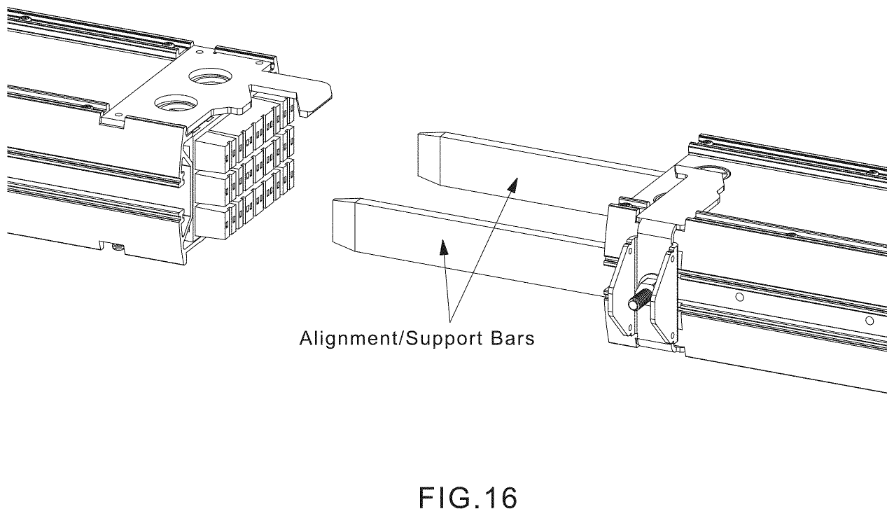

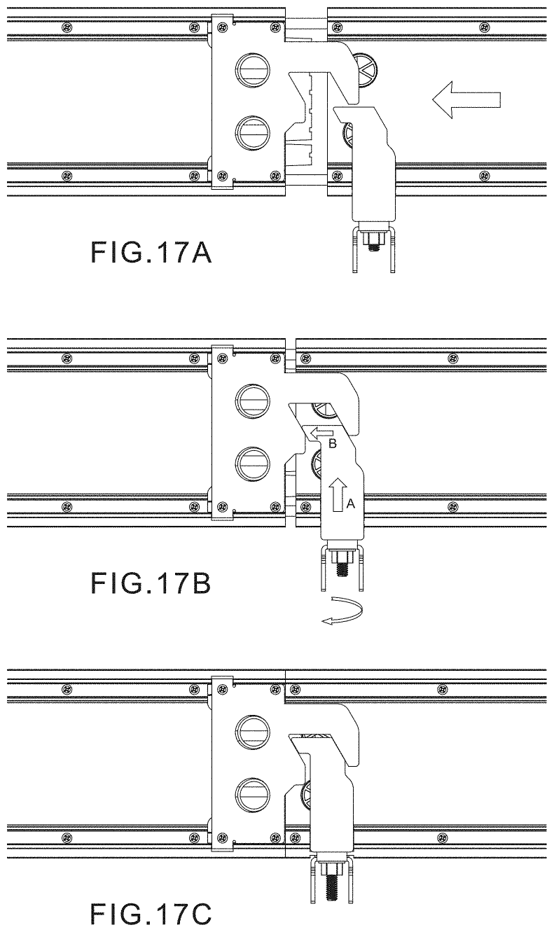

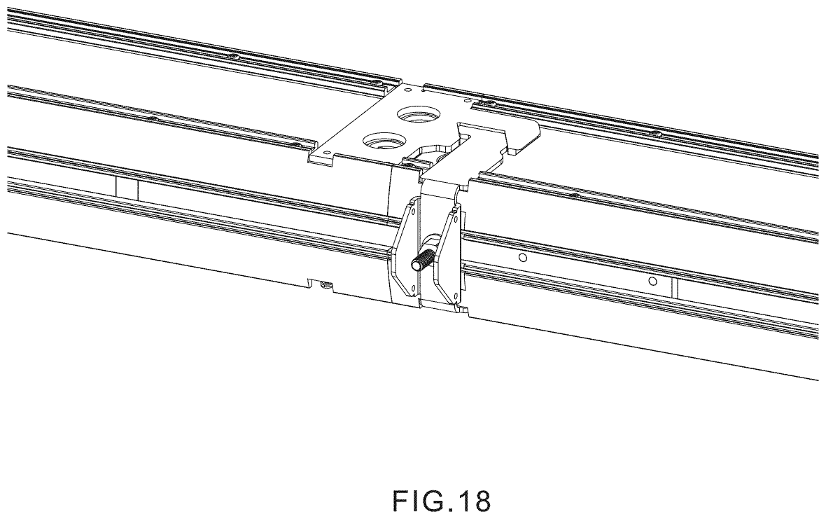

The main parts of the mechanism are Wedge, Driving Nut and Stud (part of the inserting module), and Receiver (part of receiving module) as shown in FIG. 14 and FIG. 15. An alignment/support bar (FIG. 16) would be used to aid the insertion process. AS follows:
Step 1: Power modules are first aligned with each other.
Step 2: Driving nut is rotated using a simple tool such as nut driver or ratchet. As the nut is driven, the wedge moves in the Y direction, engages the Receiver and slides in the X direction, thereby moving and inserting one power module into the other.
Step 3: At end of the travel, both the power modules and all the contact terminals will be fully engaged and locked in place as shown in FIGS. 6A and 6B.

To separate the two power modules, steps 1, 2, and 3 are done in reverse order. There is a certain amount of insertion force requirement when mating the male/female terminals to create the connection. Insertion force for a single terminal could be approximately −10 lbs. With multitude of terminals within the power connector being used (18 terminals in this embodiment) to power numerous IT equipment, connecting male and female connectors would require significant amount of force. A coupling mechanism was designed that would provide a mechanical advantage to the installer such that modules with multiple terminals are connected with simple tools (ex: nut driver) without any special tooling.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

1. A modular system for the distribution of power comprising:
a power extension module configured to route inputted power to one of a second power extension module or a power distribution module; and
a power distribution module configured to route power from a power extension module to a rack or cabinet wherein the power extension module and power distribution module have electrical connections on the ends of the modules each configured to connect to either a power extension module or a power distribution module.

2. The modular system of claim 1 further comprising a power feed module.

3. The modular system of claim 2 further comprising a breaker module.

4. The modular system of claim 1 wherein the connections are further configured to be symmetrical
